(19) United States
(12) Patent Application Publication
(10) Pub. No.: US 2008/0230771 A1
(43) Pub. Date: Sep. 25, 2008

(54) THIN FILM TRANSISTOR AND METHOD FOR MANUFACTURING THE SAME

(76) Inventors: Isao TAKASU, Kawasaki-Shi (JP); Tsuyoshi HIOKI, Yokohama-Shi (JP); Isao AMEMIYA, Tokyo (JP); Shuichi UCHIKOGA, Tokyo (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 12/045,755

(22) Filed: Mar. 11, 2008

(30) Foreign Application Priority Data
Mar. 23, 2007 (JP) 2007-76690

(51) Int. Cl. H01L 51/05; H01L 51/40

(52) U.S. Cl. 257/40; 438/99; 257/E51.006

(57) ABSTRACT

It is made possible to provide a thin film transistor having transistor characteristics that do not widely vary. A thin film transistor includes: a substrate; a pair of insulating layers formed at a distance from each other on the substrate; a source electrode formed on one of the insulating layers, and a drain electrode formed on the other one of the insulating layers; a semiconductor layer formed to cover the source electrode, the drain electrode, and the substrate; a gate insulating film formed on the semiconductor layer; and a gate electrode formed on the gate insulating film.

### CROSS-REFERENCE TO RELATED APPLICATION

This application is based upon and claims the benefit of priority from prior Japanese Patent Application No. 2007-76690 filed on Mar. 23, 2007 in Japan, the entire contents of which are incorporated herein by reference.

### BACKGROUND OF THE INVENTION

1. Field of the Invention

The present invention relates to a thin film transistor and a method for manufacturing the thin film transistor.

2. Related Art

In recent years, organic thin-film transistors having semiconductor layers made of organic materials have been developed. An organic thin-film transistor characteristically has all the components formed by printing, except for the substrate. More specifically, a soluble organic semiconductor material is used as the semiconductor layer, and a soluble high-molecular insulating material is used as the gate insulating film. Further, a metal nanoparticle dispersion ink or an organic conductive ink such as PEDOT: PSS (polyethylene-dioxy-thiophene/polystyrene sulphonic acid) is used for the electrodes. In this manner, a thin film transistor can be formed by a printing or a coating technique (see JP-A 2007-5698 (KOKAI), for example). It is considered that, by this simple method that does not involve photolithography, large-area devices and low-cost devices can be formed.

In each of those thin film transistors that have organic semiconductors and are formed by a printing or coating technique, there is the problem of poor adhesion of the organic semiconductor layer to the source and drain electrodes. More specifically, the adhesion of the organic semiconductor layer to the side faces of the source and drain electrodes is insufficient. As a result, the effective gate length changes, and the transistor characteristics vary and become unstable. Also, air bubbles enter the void formed between the organic semiconductor and the source and drain electrodes. This might cause trouble, as air bubbles appear in later procedures in the device manufacturing.

Also, materials formed by printing are generally fragile, and washing those materials with a liquid is difficult. For example, how to clean the channel region after the source and drain electrodes are formed by printing still remains a problem.

### SUMMARY OF THE INVENTION

The present invention has been made in view of these circumstances, and an object thereof is to provide a thin film transistor having transistor characteristics that do not widely vary, and a method for manufacturing such a thin film transistor.

A thin film transistor according to a first aspect of the present invention includes: a substrate; a pair of insulating layers formed at a distance from each other on the substrate; a source electrode formed on one of the insulating layers, and a drain electrode formed on the other one of the insulating layers; a semiconductor layer formed to cover the source electrode, the drain electrode, and the substrate; a gate insulating film formed on the semiconductor layer; and a gate electrode formed on the gate insulating film.

A method for manufacturing such a thin film transistor according to a second aspect of the present invention includes: applying a photosensitive resin onto a substrate to form a photosensitive resin layer; dropping a liquid containing a conductive ink material onto the photosensitive resin layer by an ink jet technique to form a source electrode and a drain electrode, the source electrode and the drain electrode being separated from each other; patterning the photosensitive resin layer through light irradiation, with the source electrode and the drain electrode serving as masks to form insulating layers under the source electrode and the drain electrode; and forming a semiconductor layer on the substrate, so as to cover the source electrode and the drain electrode.

A method for manufacturing such a thin film transistor according to a third aspect of the present invention includes: dropping a resin liquid onto a substrate by an ink jet technique to form a pair of resin layers, the resin layers being separated from each other; dropping a liquid containing a conductive ink material onto the resin layers by an ink jet technique to form a source electrode and a drain electrode; and forming a semiconductor layer on the substrate, so as to cover the source electrode and the drain electrode.

### BRIEF DESCRIPTION OF THE DRAWINGS

FIG. 1 is a cross-sectional view of a thin film transistor in accordance with a first embodiment of the present invention;

FIG. 2 is a cross-sectional view illustrating the effects of the first embodiment;

FIG. 3 is a cross-sectional view of a thin film transistor of a comparative example;

FIGS. 4A to 4C are cross-sectional views illustrating a method for manufacturing the thin film transistor in accordance with the first embodiment;

FIG. 5 is a cross-sectional view illustrating a preferred positional relationship between the gate electrode and the source/drain electrodes of the thin film transistor;

FIG. 6 is a cross-sectional view of a thin film transistor in accordance with a second embodiment of the present invention; and

FIGS. 7A and 7B are cross-sectional views illustrating a method for manufacturing the thin film transistor in accordance with the second embodiment.

### DESCRIPTION OF THE EMBODIMENTS

The following is a description of embodiments of the present invention, with reference to the accompanying drawings.

### First Embodiment

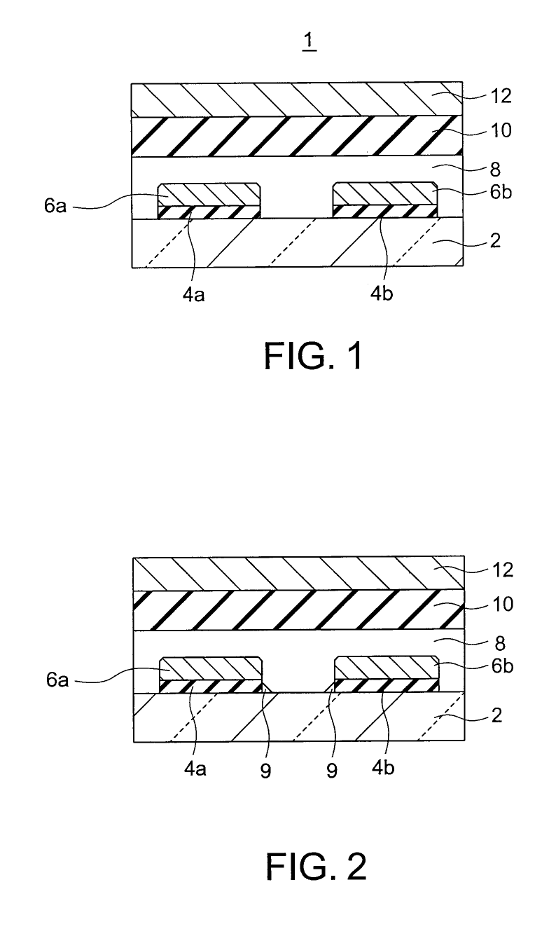

FIG. 1 is a cross-sectional view of a thin film transistor in accordance with a first embodiment of the present invention. The thin film transistor of this embodiment is a thin film transistor of a top gate structure, and has a pair of insulating layers 4a and 4b interposed between a substrate 2 and source and drain electrodes 6a and 6b. More specifically, the pair of insulating layers 4a and 4b are formed at a distance from each other on the substrate 2. The source electrode 6a is formed on the insulating layer 4a, and the drain electrode 6b is formed on the other insulating layer 4b. A semiconductor layer 8 is formed to cover the source electrode 6a, the drain electrode 6b, and the substrate 2. A gate insulating film 10 is formed on the semiconductor layer 8, and a gate electrode 12 is formed on the gate insulating film 10.

In the thin film transistor of this embodiment having the above structure, even if the adhesion of the semiconductor layer 8 is insufficient, the insulating layers 4a and 4b serve as buffer layers, and the semiconductor layer 8 can easily cover the source and drain electrodes 6a and 6b. Accordingly, voids do not readily appear. Even if voids 9 are formed between the semiconductor layer 8 and the side faces of the stacked structure formed with the insulating layers 4a and 4b and the source and drain electrodes 6a and 6b, the voids 9 are located on the side faces of the insulating layers 4a and 4b, but are not seen on the side faces of the source and drain electrodes 6a and 6b, as shown in FIG. 2. Accordingly, the effective gate length does not change, and the transistor characteristics do not widely vary but become stable.

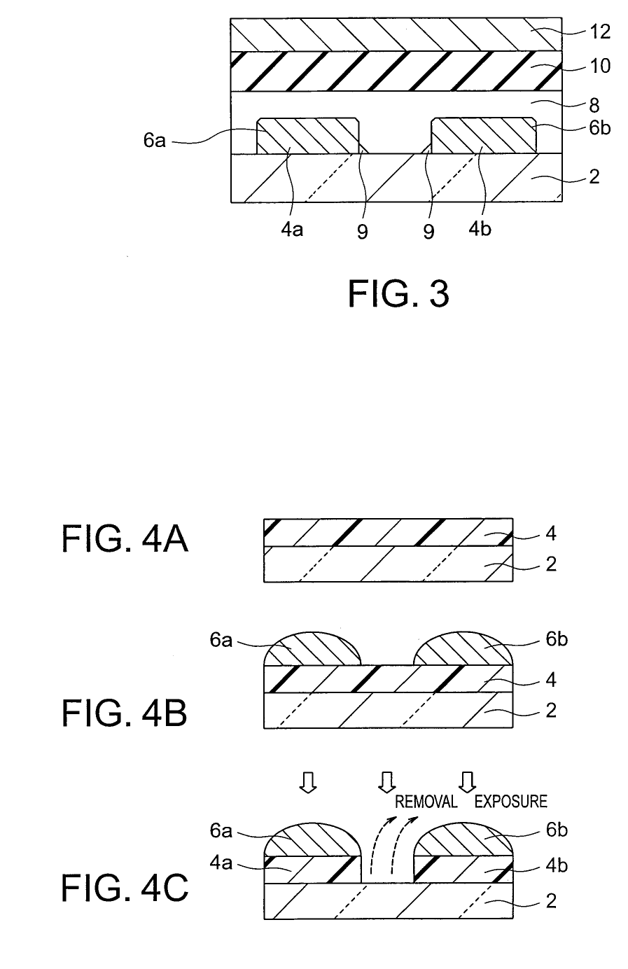

On the other hand, in a case where a pair of insulating layers are not provided between the substrate 2 and the source and drain electrodes 6a and 6b, as shown in FIG. 3, voids 9 are formed on the side faces of the source and drain electrodes 6a and 6b. As a result, the effective gate length changes, and the transistor characteristics vary and become unstable.

In this embodiment, the thickness of the semiconductor layer 8 formed on the source and drain electrodes 6a and 6b is in the range of approximately 50 nm to 1 μm. Therefore, it is preferable that the layer thickness of each of the insulating layers 4a and 4b under the source and drain electrodes 6a and 6b is close to the layer thickness of the semiconductor layer 8, and more specifically, is in the range of 50 nm to 1 μm, which is less than the thickness ten times as large as the thickness of the semiconductor layer 8.

Referring now to FIGS. 4A to 4C, a method for manufacturing the thin film transistor of this embodiment is described. By this manufacturing method, the source and drain electrodes 6a and 6b are formed by an ink jet device, and the insulating layers 4a and 4b under the source and drain electrodes 6a and 6b are made of a photosensitive resin.

First, a positive photoresist that is a photosensitive resin is applied onto the glass substrate 2 by a spin coating technique, so as to form a resist film 4 (FIG. 4A). Printing and patterning with silver nanoparticle dispersion ink is performed by an ink jet device, so as to form the source and drain electrodes 6a and 6b on the resist film 4 (FIG. 4B). Light is then emitted onto the upper faces of the source and drain electrodes 6a and 6b, and the exposure unit of the photoresist 4 is made soluble. In this manner, the insulating layers 4a and 4b are formed (FIG. 4C). After that, a remover is added, and the exposed portion of the resist film 4 is removed by washing. The semiconductor layer 8, the gate electrode film 10, and the gate electrode 12 are formed, so as to complete the thin film transistor shown in FIG. 1.

By this manufacturing method, the source and drain electrodes 6a and 6b are used as photomasks. Accordingly, the insulating layers 4a and 4b having the same shapes as the source and drain electrodes 6a and 6b in the planar direction can be formed by the patterning under the source and drain electrodes 6a and 6b.

In a case where an electrode pattern is formed on a substrate by an ink jet device, it is considered that thorough washing with a liquid is difficult, because of the brittleness of the electrode. By the method in accordance with this embodiment, however, the exposed portion of the resist corresponding to the channel region of the transistor is removed, so that foreign matter can be promptly eliminated.

By this manufacturing method, a silver nanoparticle material is used as the material for the source and drain electrodes. However, any conductive metal material, such as gold, silver, copper, platinum, or nickel, may be employed, and it is also possible to use a conductive oxide material.

The semiconductor layer 8 is formed by dissolving a soluble organic semiconductor in an organic solvent and performing spin coating. The semiconductor solution may be turned into a film by a printing technique using an ink jet device or the like. In a case of a low-molecular organic semiconductor, film formation may be carried out by the vacuum vapor deposition method. However, the formation of a semiconductor film should preferably be carried out through a liquid process, because of its simplicity and convenience.

The gate insulating film 10 is formed by performing spin coating with a solution obtained by dissolving an insulating high-molecular material in an organic solvent or water, or performing printing by an ink jet technique or the like.

The gate electrode 12 may be formed or patterned by performing spin coating with a conductive organic ink such as PEDOT: PSS or a metal nanoparticle ink such as silver nanoparticle dispersion ink or by a printing technique using an ink jet device.

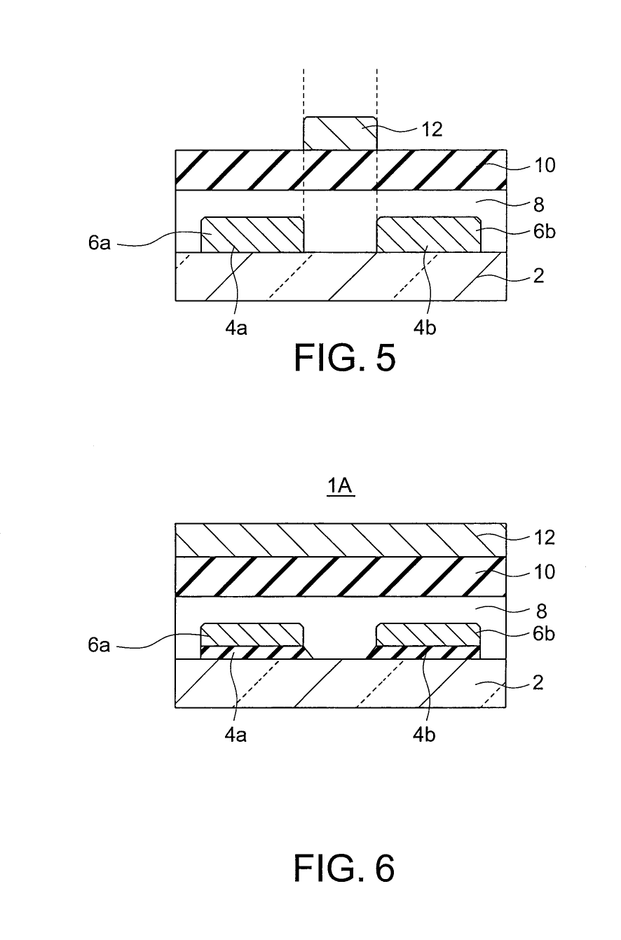

Particularly, by patterning the gate electrode 12 so as to conform to the channel region interposed between the source and drain electrodes 6a and 6b, loss of applied voltage and an increase in parasitic capacitance can be prevented while the transistor is driven. Therefore, it is preferable that the end faces of the source and drain electrodes 6a and 6b facing the channel region are located in the same planes as the end faces of the gate electrode 12, as shown in FIG. 5. With this arrangement, more preferred transistor characteristics can be achieved.

Examples of materials for the insulating layers 4a and 4b include polyethylene, polystyrene, acrylonitrile-styrene copolymer, ABS resin, AES resin, polypropylene, polyvinyl chloride, polyvinylidene chloride, methacrylate, polyacrylic acid, polyvinyl acetate, polyamide, unsaturated polyester, polycarbonate, alkyd resin, silicone resin, epoxy resin, acetal resin, polyallylester, polyimide, polyether ketone, polyether sul, polyphenylene oxide, polyphenylene sulfide, and phenol resin.

An insulating metal oxide, such as silicon oxide, aluminum oxide, or tantalum oxide, may also be used as the material for the insulating layers 4a and 4b. It is also possible to use a resin material containing an insulating metal oxide that is formed by combining an insulating metal oxide and one of the above mentioned resin materials.

Examples of preferred materials for the semiconductor layer 8 include condensed aromatic compounds such as pentacene and tetracene, derivatives of those aromatic compounds formed by substituting them for alkyl chains or the likes, high-molecular materials having conjugated chains such as polythiophene, poly-para-phenylene, polypyrrole, and polyaniline, and derivatives of those high-molecular materials formed by substituting them for alkyl chains or the likes. Particularly, in a thin film transistor of a top gate type, the flatness of the semiconductor layer and the gate insulating layer is essential. In view of this, it is more preferable that a high-molecular semiconductor layer material is employed.

Examples of preferred materials for the gate insulating film 10 include insulating high-molecular materials such as polyvinyl phenol, polyethylene materials, and epoxy resins.

Examples of preferred photosensitive resins include photosensitive polyimide and photosensitive acrylic resin. A positive resist material such as a novolac/azide material or polymethyl methacrylate (PMMA) may also be used. With any of those materials, depending on the reach of light at the time of the photosensitive reaction using a mask, tapered end faces are formed after the removal with an etching liquid as in a second embodiment described later. Utilizing this phenomenon, a tapered structure of insulating layers can be obtained.

### Second Embodiment

FIG. 6 shows a thin film transistor in accordance with a second embodiment of the present invention. The thin film transistor 1A of this embodiment has the same structure as the thin film transistor 1 of the first embodiment shown in FIG. 1, except that the end faces of the insulating layers 4a and 4b facing the channel region are tapered faces extending toward the channel region.

Since the end faces of the insulating layers 4a and 4b facing the channel region are tapered faces in this embodiment, voids are not easily formed between the semiconductor layer 8 and the end faces of the insulating layers 4a and 4b facing the channel region. Even if voids are formed, the voids are located between the semiconductor layer 8 and the end faces of the insulating layers 4a and 4b on the side of the channel region, but are not seen between the semiconductor layer 8 and the side faces of the source and drain electrodes 6a and 6b. Accordingly, the effective gate length does not change, and the transistor characteristics do not widely vary but become stable, as in the first embodiment.

In this embodiment, the thickness of the semiconductor layer 8 formed on the source and drain electrodes 6a and 6b is in the range of approximately 50 nm to 1 μm. Therefore, it is preferable that the layer thickness of each of the insulating layers 4a and 4b under the source and drain electrodes 6a and 6b is close to the layer thickness of the semiconductor layer 8, and more specifically, is in the range of 50 nm to 1 μm, which is less than the thickness ten times as large as the thickness of the semiconductor layer 8.

The thin film transistor of this embodiment can be manufactured by the same method as the manufacturing method in accordance with the first embodiment, except that the tapered structure is formed by adjusting the type of photoresist and the incident light.

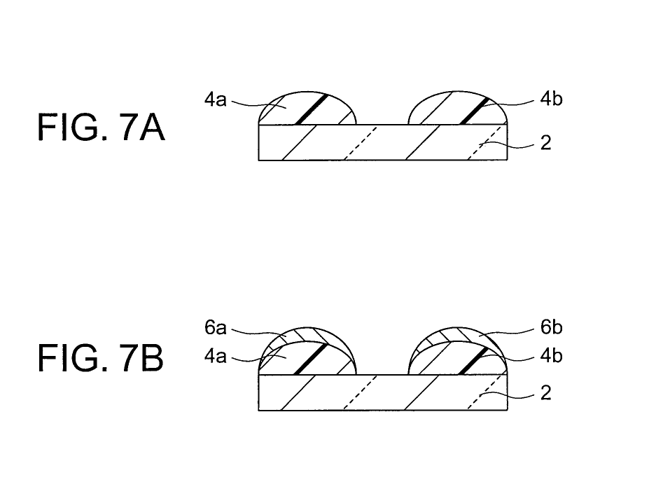

Also, as shown in FIGS. 7A and 7B, the insulating layers 4a and 4b may be formed with a resin material by an ink jet device.

First, patterning is performed on the substrate 2 by an ink jet device, so as to form an insulating resin material into the same shape as an object source/drain electrode structure, except for a slight enlargement in the planar direction. In this manner, the insulating layers 4a and 4b are formed (FIG. 7A). The source and drain electrodes 6a and 6b are then formed on the insulating layers 4a and 4b by an ink jet device (FIG. 7B). Here, the covered area of the source and drain electrodes 6a and 6b should preferably be smaller than the covered area of the insulating layers 4a and 4b. Also, the resin layers 4a and 4b formed by an ink jet device have the tapered end portions formed through a liquid process, which is characteristic of the second embodiment.

As in the first embodiment, the semiconductor layer 8, the gate insulating film 10, and the gate electrode 12 are then formed in a sequential manner, so as to complete the thin film transistor 1A.

As described above, in accordance with each of the embodiments of the present invention, a thin film transistor having stable transistor characteristics that do not vary can be obtained. In a case where a photosensitive resin is used for the insulating layers, and the process of removing the resin in the channel region is carried out through exposure, the channel region can be cleaned as well.

Additional advantages and modifications will readily occur to those skilled in the art. Therefore, the invention in its broader aspects is not limited to the specific details and representative embodiments shown and described herein.

Accordingly, various modifications may be made without departing from the spirit or scope of the general inventive concepts as defined by the appended claims and their equivalents.

What is claimed is:

1. A thin film transistor comprising:
a substrate;
a pair of insulating layers formed at a distance from each other on the substrate;
a source electrode formed on one of the insulating layers, and a drain electrode formed on the other one of the insulating layers;
a semiconductor layer formed to cover the source electrode, the drain electrode, and the substrate;
a gate insulating film formed on the semiconductor layer; and
a gate electrode formed on the gate insulating film.

2. The transistor according to claim 1, wherein the insulating layers have side faces facing each other, the side faces being tapered side faces extending between the insulating layers.

3. The transistor according to claim 1, wherein the gate electrode has end faces in the same planes as side faces of the insulating layers facing each other, the end faces of the gate electrode facing opposite from each other in the direction in which the insulating layer is separated from each other.

4. The transistor according to claim 1, wherein the semiconductor layer is made of an organic material.

5. The transistor according to claim 1, wherein the insulating layers are made of a photosensitive resin.

6. A method for manufacturing a thin film transistor, comprising:
applying a photosensitive resin onto a substrate to form a photosensitive resin layer;
dropping a liquid containing a conductive ink material onto the photosensitive resin layer by an ink jet technique to form a source electrode and a drain electrode, the source electrode and the drain electrode being separated from each other;
patterning the photosensitive resin layer through light irradiation, with the source electrode and the drain electrode serving as masks to form insulating layers under the source electrode and the drain electrode; and
forming a semiconductor layer on the substrate, so as to cover the source electrode and the drain electrode.

7. The method according to claim 6, wherein the semiconductor layer is made of an organic material.

8. A method for manufacturing a thin film transistor, comprising:
dropping a resin liquid onto a substrate by an ink jet technique to form a pair of resin layers, the resin layers being separated from each other;
dropping a liquid containing a conductive ink material onto the resin layers by an ink jet technique to form a source electrode and a drain electrode; and
forming a semiconductor layer on the substrate, so as to cover the source electrode and the drain electrode.

9. The method according to claim 8, wherein the semiconductor layer is made of an organic material.
